(19) United States
(12) Patent Application Publication
(10) Pub. No.: US 2013/0271900 A1
(43) Pub. Date: Oct. 17, 2013

(54) ELECTRONIC DEVICE WITH HIGH DEFINITION MULTIMEDIA INTERFACE

(71) Applicant: TAO WANG, Shenzhen City (CN)

(72) Inventor: TAO WANG, Shenzhen City (CN)

(21) Appl. No.: 13/651,653

(22) Filed: Oct. 15, 2012

(30) Foreign Application Priority Data
Apr. 11, 2012 (CN) 201210104606.0

(51) Int. Cl. H05K 7/00

(52) U.S. Cl. 361/679.01

(57) ABSTRACT

An electronic device includes a high definition multimedia interface (HDMI) a power module, and a unidirectional switch. The HDMI includes a power pin, the power module includes a power output port. The unidirectional switch is forward biased between the power output port of the power module and the power pin of the HDMI.

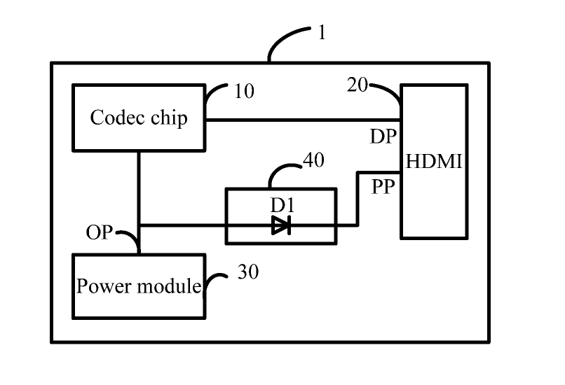

### BACKGROUND

1. Technical Field

The present disclosure relates to electronic devices and, particularly, to an electronic device with a high definition multimedia interface.

2. Description of Related Art

Electronic devices equipped with a high definition multimedia interface (HDMI) are more and more popular. For example, television sets and digital video disk (DVD) players are usually equipped with the high definition multimedia interface. Commonly, in order to control the television set and the DVD player by one remote controller, the television set and the DVD player both adopt a HDMI consumer electronics control (CEC) protocol. However, when the television set and DVD player adopt the HDMI CEC protocol and the television set is connected to the DVD player via a HDMI line, if one of the television set and the DVD player is powered on and the other is powered off, the one powered on would provide power to the other one via the HDMI line, and cause the other one to become unstable when the other one is powered on again.

Therefore, an electronic device with a high definition multimedia interface, to overcome the described limitations is thus needed.

### BRIEF DESCRIPTION OF THE DRAWINGS

Many aspects of the present disclosure are better understood with reference to the following drawing. The components in the drawing are not necessarily drawn to scale, the emphasis instead being placed upon clearly illustrating the principles of the present disclosure. Moreover, in the drawing, like reference numerals designate corresponding parts throughout the view.

The FIGURE is a circuit diagram of an electronic device with a high definition multimedia interface, in accordance with an exemplary embodiment.

### DETAILED DESCRIPTION

Embodiments of the present disclosure will be described with reference to the accompanying drawing.

The FIGURE illustrates an electronic device 1 with a high definition multimedia interface (HDMI) of the embodiment. The electronic device 1 includes a codec chip 10, a HDMI 20, a power module 30, and a unidirectional switch 40.

The HDMI 20 includes a power pin PP and a data pin DP. The codec chip 10 is connected to the data pin DP of the HDMI 20, and is used to code data transmitted to the data pin DP of the HDMI 20, and then the coded data is transmitted to other electronic devices via the HDMI 20. The code chip 10 is also used to decode data received from the data pin DP of the HDMI 20, when the HDMI 20 receives the data from other electronic devices.

The power module 30 includes a power output port OP. The power module 30 provides power to the codec chip 10, the HDMI 20 and other elements of the electronic device 1 via the power output port OP.

The unidirectional switch 40 is forward biased between the power output port OP of the power module 30 and the power pin PP of the HDMI 20, and conducts power from the power module 30 to the power pin PP of the HDMI 20.

In the embodiment, the unidirectional switch 40 includes a diode D1, an anode of the diode D1 is connected to the power output port OP, and a cathode of the diode D1 is connected to the power pin PP of the HDMI 20.

When the electronic device 1 is powered on, the power module 30 provides power to the codec chip 10 via the power output port OP, and provides power to the HDMI 20 via the power output port OP and the diode D1. Therefore, the codec chip 10 and the HDMI 20 are powered on and working.

When the electronic device 1 is powered off, the power module 30 stops providing power to the codec chip 10 and the HDMI 20. In this case, the electronic device 1 is connected to another electronic device 1 which is powered on via the HDMI 20, and the electronic device 1 and the other electronic device both have a HDMI consumer electronics control (CEC) protocol. As previously pointed out, the other electronic device would provide power to the electronic device 1 via the HDMI 20 of related art. However, the diode D1 prevents the power from the HDMI 20 being supplied in a reverse direction and avoids the electronic device 1 becoming unstable for when the electronic device 1 is powered on again.

In the embodiment, the electronic device 1 can be a television set, or a digital video disk player, or a digital set-top box, for example. Particularly, in the embodiment, the electronic device 1 does adopt the HDMI CEC protocol.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. An electronic device comprising:
a high definition multimedia interface (HDMI) comprising a power pin;
a power module comprising a power output port, and
a unidirectional switch being forward biased between the power output port of the power module and the power pin of the HDMI.

2. The electronic device according to claim 1, wherein the HDMI further comprises a data pin, the electronic device further comprises a codec chip, the codec chip is connected to the data pin of the HDMI, and is configured to code data transmitted to the data pin of the HDMI, and is further configured to decode data received from the data pin of the HDMI.

3. The electronic device according to claim 1, wherein the unidirectional switch comprises a diode, an anode of the diode is connected to the power output port of the power module, and a cathode of the diode is connected to the power pin of the HDMI.

4. The electronic device according to claim 1, wherein when the electronic device is powered on, the power module provides power to the HDMI via the power output port and the unidirectional switch.

5. The electronic device according to claim 1, wherein when the electronic device is powered off, the unidirectional switch prevents the power from the HDMI to the power module.

6. The electronic device according to claim 1, wherein the electronic device is one selected from a group consist of a television set, a digital video disk player, and a digital set-top box.

7. The electronic device according to claim 1, wherein the electronic device adopts a HDMI consumer electronics control (CEC) protocol.
